(19) United States
(12) Patent Application Publication
(10) Pub. No.: US 2023/0403815 A1
(43) Pub. Date: Dec. 14, 2023

(54) HIGH-POWER THERMOELECTRIC CHILLER FOR COMPUTING MACHINES

(71) Applicants: Benjamin K. Sharfi, Rancho Cucamonga, CA (US); Saul Gonzalez, Rancho Cucamonga, CA (US); Kadek W. Hemawan, Rancho Cucamonga, CA (US)

(72) Inventors: Benjamin K. Sharfi, Rancho Cucamonga, CA (US); Saul Gonzalez, Rancho Cucamonga, CA (US); Kadek W. Hemawan, Rancho Cucamonga, CA (US)

(21) Appl. No.: 18/333,277

(22) Filed: Jun. 12, 2023

Related U.S. Application Data
(60) Provisional application No. 63/366,164, filed on Jun. 10, 2022.

(51) Int. Cl. H05K 7/20

(52) U.S. Cl. CPC H05K 7/20154; H05K 7/20209; H05K 7/20409; H05K 7/20454; H05K 2201/10219

(57) ABSTRACT

A thermoelectric chiller for cooling an electronic device comprising a chassis and a heatsink, the heatsink having a flat side and an opposing side equipped with cooling fins, the chassis and heatsink adapted for cooperative engagement to create an air-sealed chamber with the heatsink cooling fins inside the chamber; a cold air inlet on an inlet side of the chamber, the cold air inlet equipped with one or more fans adapted to force ambient air into the chamber; a hot air exhaust on an exhaust side of the chamber, the hot air exhaust providing an outlet for air to leave the chamber; one or more Peltier effect elements, each having a hot side and a cold side, the one or more Peltier effect elements disposed so that their hot side is in thermal contact with the flat side of the heat sink; a cold plate disposed over the one or more Peltier effect elements and in thermal contact with the cold side of the one or more Peltier effect elements; a controller to control the operation of the one or more fans and the one or more Peltier effect elements.

### CLAIM OF PRIORITY

This application is being filed as a non-provisional patent application under 35 U.S.C. § 111(a) and 37 CFR § 1.53(b). This application claims priority under 35 U.S.C. § 119(e) to U.S. provisional patent application Ser. No. 63/366,164 filed on Jun. 10, 2022, the contents of which are incorporated herein by reference.

### FIELD OF INVENTION

The present invention relates to cooling devices in the field of electronics. More specifically, the present invention relates to a cooling thermal management device for efficiently dissipating heat generated by thermal energy sources, such as CPUs or GPUs from computing machines or servers.

### SUMMARY OF THE INVENTION

Disclosed is a cooling thermal management device for efficiently dissipating heat generated by thermal energy sources, such as CPU or GPU processors from computing machines or servers. This system is unique because of its compact size, high-cooling power, and is embedded with a thermoelectric cooler module. Currently, there is a very limited computer chiller commercially available in the market with a thermoelectric element of this size with cooling power up to 500 W.

The size of this advanced cooling system is very compact as low as 1 U to 2 U rack server system height, custom-designed metal sheet heat sink with specific cut-outs fins to allow airflow from the cold air inlet to the hot air outlet exhaust system.

The connection between the Peltier elements, the cold plate, and the heat sink is secured by using liquified diamond thermal interface coolant and set screws on its side. The cold plate facilitates the heat transfer via conduction from the cold side of the Peltier elements to cool the high-power heat source.

The device consists of a cold plate, multiple thermoelectric Peltier elements configured in a parallel circuit, a controller, heat sink element, thermistor sensors, air-cooling fans, and an enclosure chassis.

### BRIEF DESCRIPTION OF THE DRAWINGS

FIG. 1 is an exploded view of a thermoelectric chiller in accordance with an embodiment of the present invention.

FIG. 2 is an assembled view of a thermoelectric chiller in accordance with an embodiment of the present invention.

FIG. 3 shows an example of a heat load or computer device installed on a thermoelectric chiller in accordance with an embodiment of the present invention.

FIG. 4 shows a thermal simulation illustrating the temperature gradients achieved on the cold plate side of a thermoelectric chiller in accordance with an embodiment of the present invention.

FIG. 5 shows a thermal simulation illustrating the temperature gradients achieved on the hot plate side of a thermoelectric chiller in accordance with an embodiment of the present invention.

FIG. 6 illustrate the results of experiments conducted to determine cooling efficacy of a thermoelectric chiller in accordance with an embodiment of the present invention.

### DETAILED DESCRIPTION OF THE INVENTION

Following is a detailed descriptions of several aspects of the present invention, all of which relate to the high-speed input/output signal and high-power transmission connectors and cables in accordance with embodiments of the present invention.

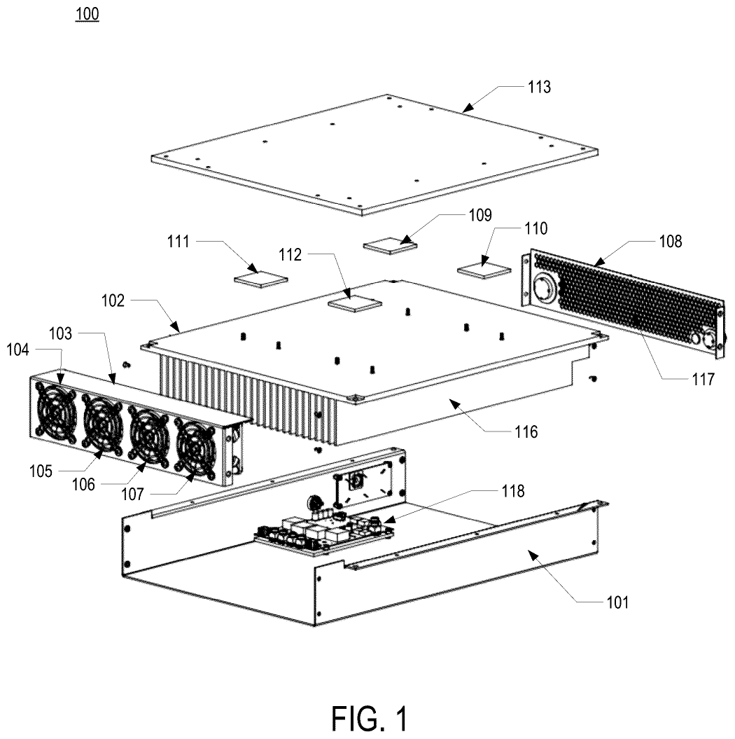

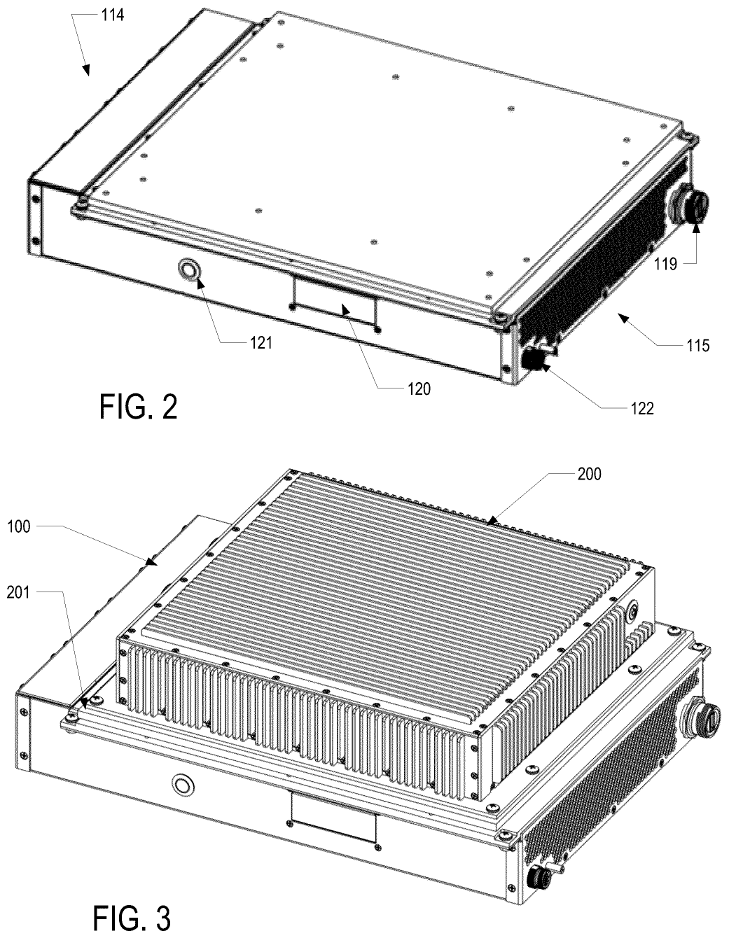

FIG. 1 is an exploded view of a thermoelectric chiller in accordance with an embodiment of the present invention. FIG. 2 is an assembled view of a thermoelectric chiller in accordance with an embodiment of the present invention.

As shown in FIGS. 1 and 2, the chiller (100) comprises the following main components: a chassis (101); a heatsink (102); a cold air inlet (103) equipped with one or more fans (104, 105, 106, 107); a hot air exhaust (108); one or more Peltier effect elements (109, 110, 111, 112); and a cold plate (113).

Heatsink (102) and chassis (101) are adapted for cooperative engagement to create a chamber for cooling air to circulate from an inlet side (114) to an exhaust side (115) of the chiller through cooling fins (116) built into heatsink (102). The top surface of heatsink (102) is adapted to accommodate the one or more Peltier effect elements (109, 110, 111, 112) with the hot side of the elements being in contact with heatsink (102). The cold side of the one or more Peltier effect elements (109, 110, 111, 112) is adapted to receive a cold plate (113), upon which an electronic component may be installed using an adaptor plate (201) (see FIG. 3). In some embodiments, the interface between the Peltier effect elements (109, 110, 111, 112), the cold plate (113) and the heatsink (102) comprises a liquified diamond thermal paste (not shown).

The cold air inlet (103) is located on the inlet side (114) of the chiller (100), and the hot air exhaust (108) is located in the exhaust side (115) of the chiller (100). The hot air exhaust (108) is optionally equipped with a protective grill (117) and the cold air inlet (103) can optionally be equipped with an air filter (not shown). In some embodiments, the hot air exhaust (108) can also be equipped with an air filter (not shown) and the one or more fans (104, 105, 106, 107) are reversable enabling the direction of airflow to be reversed.

The one or more fans (104, 105, 106, 107) and Peltier effect elements (109, 110, 111, 112) are controlled by a controller board (118) located inside chassis (101). The controller board (118) receives power and, optionally, data commands through an input port (119) accessible from outside the chiller (100). The controller board (118) may also optionally be connected to a digital display (120) and an activation button (121) which provide status information (e.g., inside temperature, ambient temperature, errors and faults, etc.) to an operator. The chiller (100) is also equipped with a master on/off button (122) connected to the controller board (118) which activates and deactivates the chiller (100).

In operation, once the chiller (100) is activated, the Peltier effect elements (109, 110, 111, 112) are turned on, cooling the cold plate (113), and transferring heat into the heatsink (102). The one or more fans (104, 105, 106, 107) force ambient air into the chassis (101) through the cold air inlet (103) and the cooling fins 116 of the heatsink (102), and out of the hot air exhaust (108) through the protective grill (117). This process provides overall cooling to any equipment attached to the cold plate (113).

FIG. 3 shows an example of a heat load or computer device installed on a thermoelectric chiller in accordance with an embodiment of the present invention. As shown the device to be cooled (200) is attached to the chiller (100) by means of an optional adapter plate (201). The adapter plate provides two patterns of screw holes that match corresponding patterns on the cold plate (113) and mounting base of the device (200) respectively.

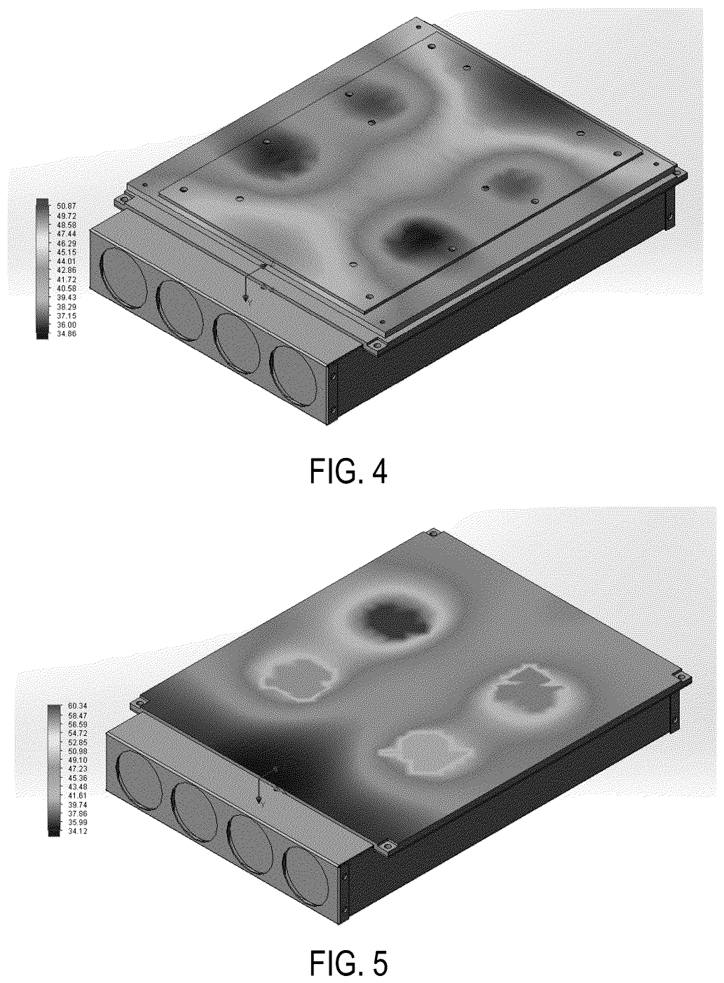

FIG. 4 shows a thermal simulation illustrating the temperature gradients achieved on the cold plate side of a thermoelectric chiller in accordance with an embodiment of the present invention. As can be seen, significant cooling is achieved on the cold plate (113) and adaptor plate (201) which is transferred to the device.

FIG. 5 shows a thermal simulation illustrating the temperature gradients achieved on the hot plate side of a thermoelectric chiller in accordance with an embodiment of the present invention. As can be seen, significant heat is transferred to the heat sink (102) which is dissipated by the air flowing through the chiller (100).

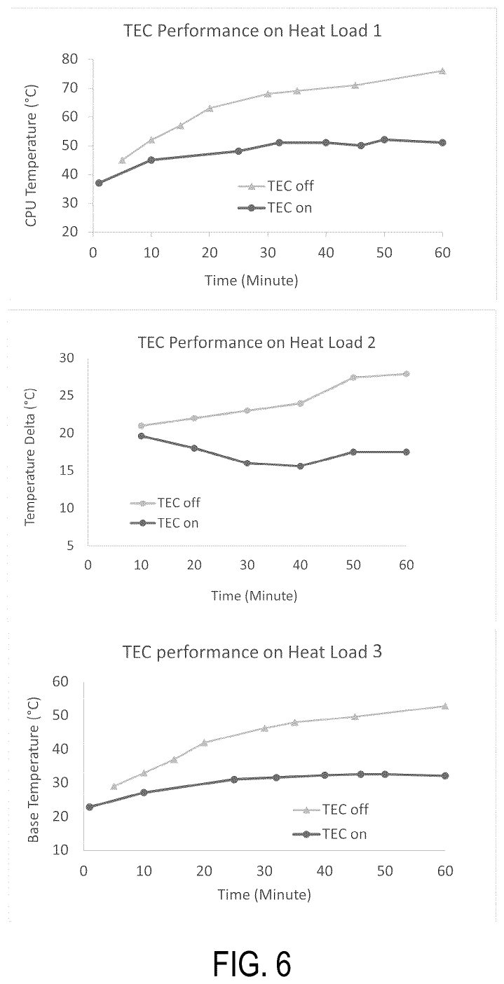

FIG. 6 illustrate the results of experiments conducted to determine cooling efficacy of a thermoelectric chiller in accordance with an embodiment of the present invention. Three different charts are provided to illustrate the temperatures achieved with the chiller in the on and off positions.

Although described above in connection with particular hardware configurations and standards, these descriptions are not intended to be limiting as various modifications may be made therein without departing from the spirit of the invention and within the scope and range of equivalent of the described embodiments. Encompassed embodiments of the present invention can be used in all applications where efficient and high-performing electronic device interconnections are desired.

While a number of embodiments of the present invention have been described, it is understood that these embodiments are illustrative only, and not restrictive, and that many modifications may become apparent to those of ordinary skill in the art. For example, any element described herein may be provided in any desired size (e.g., any element described herein may be provided in any desired custom size or any element described herein may be provided in any desired size selected from a “family” of sizes, such as small, medium, large). Further, one or more of the components may be made from any suitable material.

In addition, various modifications and additions can be made to the exemplary embodiments discussed without departing from the scope of the present invention. For example, while the embodiments described above refer to particular features, the scope of this invention also includes embodiments having different combinations of features and embodiments that do not include all of the described features. Accordingly, the scope of the present invention is intended to embrace all such alternatives, modifications, and variations as fall within the scope of the claims, together with all equivalents thereof.

We claim:

1. A thermoelectric chiller for cooling an electronic device comprising:
a chassis and a heatsink, the heatsink having a flat side and an opposing side equipped with cooling fins, the chassis and heatsink adapted for cooperative engagement to create an air-sealed chamber with the heatsink cooling fins inside the chamber;
a cold air inlet on an inlet side of the chamber, the cold air inlet equipped with one or more fans adapted to force ambient air into the chamber;
a hot air exhaust on an exhaust side of the chamber, the hot air exhaust providing an outlet for air to leave the chamber;
one or more Peltier effect elements, each having a hot side and a cold side, the one or more Peltier effect elements disposed so that their hot side is in thermal contact with the flat side of the heat sink;
a cold plate disposed over the one or more Peltier effect elements and in thermal contact with the cold side of the one or more Peltier effect elements;
a controller to control the operation of the one or more fans and the one or more Peltier effect elements.

2. The thermoelectric chiller of claim 1 further comprising a display for displaying operational parameters of the chiller, the display controlled by the controller.

3. The thermoelectric chiller of claim 1 wherein an interface between at least one of the one or more Peltier effect elements and the heatsink comprises a liquified diamond thermal paste,

4. The thermoelectric chiller of claim 1 wherein an interface between at least one of the one or more Peltier effect elements and the cold plate comprises a liquified diamond thermal paste
